(19) United States
(12) Patent Application Publication
(10) Pub. No.: US 2007/0062646 A1
(43) Pub. Date: Mar. 22, 2007

(54) Method and apparatus for processing substrates

(75) Inventors: Unryu Ogawa, Tokyo (JP); Tetsuya Takagaki, Tokyo (JP); Akinori Ishii, Tokyo (JP); Tatsushi Ueda, Tokyo (JP); Takayuki Sato, Tokyo (JP)

Correspondence Address: BACON & THOMAS, PLLC, 625 SLATERS LANE, FOURTH FLOOR, ALEXANDRIA, VA, 22314, US

(73) Assignee: HITACHI KOKUSAI ELECTRIC INC., Tokyo (JP)

(21) Appl. No.: 11/601,697

(22) Filed: Nov. 20, 2006

Related U.S. Application Data
(63) Continuation of application No. 09/960,947, filed on Sep. 25, 2001, now abandoned.

(30) Foreign Application Priority Data
Sep. 25, 2000 (JP) 2000-290995
Jul. 12, 2001 (JP) 2001-212216

(51) Int. Cl. H01L 21/306

(52) U.S. Cl. 156/345.29; 156/345.33; 156/913

(57) ABSTRACT

A substrate processing apparatus includes a processing chamber and a gas supply line, wherein a natural oxide film removing gas including a first gas activated by a second gas activated by a plasma discharge is supplied to the processing chamber through the gas supply line to remove a natural oxide film on a wafer, and wherein the first gas and the second gas are supplied to the gas supply line along a first direction and a second direction and an angle between the first and the second direction ranges from about 90° to 180°.

### FIELD OF THE INVENTION

The present invention relates to a substrate processing apparatus; and, more particularly, to a method and apparatus for removing a natural oxide film formed on a substrate to be processed in the course of manufacturing, e.g., a semiconductor device.

### BACKGROUND OF THE INVENTION

In manufacturing a semiconductor device, a batch type vertical hot wall furnace (hereinafter, referred to as a heat-treating apparatus) is widely used to perform a heat-treatment such as a film formation, an annealing process, an oxide film forming process or a diffusion process on silicon wafers (hereinafter, referred to as wafers).

If a wafer is exposed to air while being transferred between processing stages of semiconductor device manufacturing processes, a natural oxide film is formed on the wafer due to oxygen or moisture in the air. The natural oxide film formed on the wafer is a silicon oxide film having an incomplete crystallinity. Thus, a film quality of the natural oxide film is inferior to that of a silicon oxide film formed through a controlled thermal oxidization process. Accordingly, semiconductor devices manufactured by using the wafer having the natural oxide film formed thereon exhibit many an adverse effect on their device characteristics as follows.

1) The presence of a natural oxide film at the region of an insulation film of a capacitor on a wafer results in a reduced effective capacitance of the capacitor due to an increased distance between electrodes of the capacitor and also due to a low dielectric constant of the natural oxide film.

2) If a gate oxide film is formed on the natural oxide film, a leak current increases compared to a case without having a natural oxide film because the natural oxide film oxidized by oxygen in the ambient atmosphere contains a considerable amount of contaminants. Further, since the contaminants contained in the natural oxide film may diffuse into neighboring layers thereof during a following heat-treatment process, electrical characteristics of a device can be deteriorated.

3) The existence of a natural oxide film at a contact region between an upper wiring layer and a low wiring layer of a semiconductor device having a multilayer structure, an electrical contact resistance between the layers are increased.

4) In forming a HSG (Hemispherical Grained poly Silicon) film on a wafer so as to increase a dielectric constant, the growth of the HSG film is impeded by the presence of a natural oxide film formed on the wafer.

For the reasons as described above, a natural film formed on a wafer is generally removed by cleaning the wafer with a hydrogen fluoride (hereinafter, HF) before being subject to a desired heat-treatment (hereinafter, a main treatment) process in a heat treating apparatus. However, if the cleaned wafer is exposed to air while being transferred to the heat treating apparatus, a natural oxide film having a thickness of 1 to 2 atomic layers can be formed again on the cleaned wafer. Further, since it is required to reduce a time between the finish of the cleaning processing and the beginning of the heat-treatment processing as to minimize the thickness of the natural oxide film which grows with time, a degree of design freedom of the processing line may be limited. Still further, minute trenches of scaled-down semiconductor devices may not be properly cleaned through the HF cleaning process because the HF cleaning is a wet process.

Therefore, there has been a demand to develop a natural oxide film removing method adopting a dry etching principle. As one possible method of such kinds, a natural oxide film removing method using a remote plasma cleaning technique has been developed. The remote plasma cleaning is a technique for removing residual by-products attached to the process room by introducing into the processing chamber radicals activated in a remote plasma unit disposed outside the processing chamber.

However, the natural oxide film removing method through the use of the remote plasma cleaning technique has certain drawbacks as follows. If a natural oxide film removing gas for dry-etching the natural oxide film is not properly activated, plasma damage may occur on the wafer or an etching selectivity may not be obtained, resulting in the failure to remove the natural oxide film. Further, when a plurality of wafers are simultaneously processed so as to improve a throughput, if the uniformity of natural oxide film removing gas is not maintained between the wafers and within each wafer, the natural oxide films may not be removed uniformly.

### SUMMARY OF THE INVENTION

It is, therefore, an object of the present invention to provide a substrate processing apparatus capable of uniformly removing a natural oxide film formed on each substrate to be processed without causing any plasma damage thereon but with an improved throughput.

In accordance with a preferred embodiment of the present invention, there is provided a substrate processing apparatus, including:

a processing chamber and a gas supply line,

wherein a natural oxide film removing gas including a first gas activated by a second gas activated by a plasma discharge is supplied to the processing chamber through the gas supply line to remove a natural oxide film on a wafer, and

wherein the first gas and the second gas are supplied to the gas supply line along a first direction and a second direction and an angle between the first and the second direction ranges from about 90° to 180°.

In accordance with another preferred embodiment of the present invention, there is provided a substrate processing apparatus including;

a processing chamber in which a plurality of wafers are processed at a time;

a remote plasma unit disposed outside the processing chamber for supplying an activated natural oxide film removing gas to the processing chamber; and

a distribution device which distributes the natural oxide film removing gas to flow parallel to the wafers.

### BRIEF DESCRIPTION OF THE DRAWINGS

The above and other objects and features of the present invention will become apparent from the following description of preferred embodiments given in conjunction with the accompanying drawings, in which:

FIG. 1 is a side cross sectional view of a batch type natural oxide film removing apparatus in accordance with a first embodiment of the present invention;

FIGS. 2A to 2C explain a natural oxide film removing process;

FIG. 3 provides a side cross sectional view of a single wafer type natural oxide film removing apparatus in accordance with a second embodiment of the present invention;

FIGS. 4A to 4C illustrate various locations of a gas supply line in accordance with the present invention;

FIG. 5 sets forth a side cross sectional view of a batch type natural oxide film removing apparatus in accordance with a third embodiment of the present invention;

FIG. 6 offers a top cross sectional view of the natural oxide film removing apparatus shown in FIG. 5;

FIGS. 7A to 7C show various types of distribution plates in accordance with the present invention;

FIG. 8 gives a side cross sectional view of a batch type natural oxide film removing apparatus in accordance with a fourth embodiment of the present invention; and

FIG. 9 exhibits a cross sectional view of a batch type natural oxide film removing apparatus in accordance with still another embodiment of the present invention.

### DETAILED DESCRIPTION OF THE PREFERRED EMBODIMENTS

Preferred embodiments of the present invention will now be described in detail with reference to the accompanying drawings.

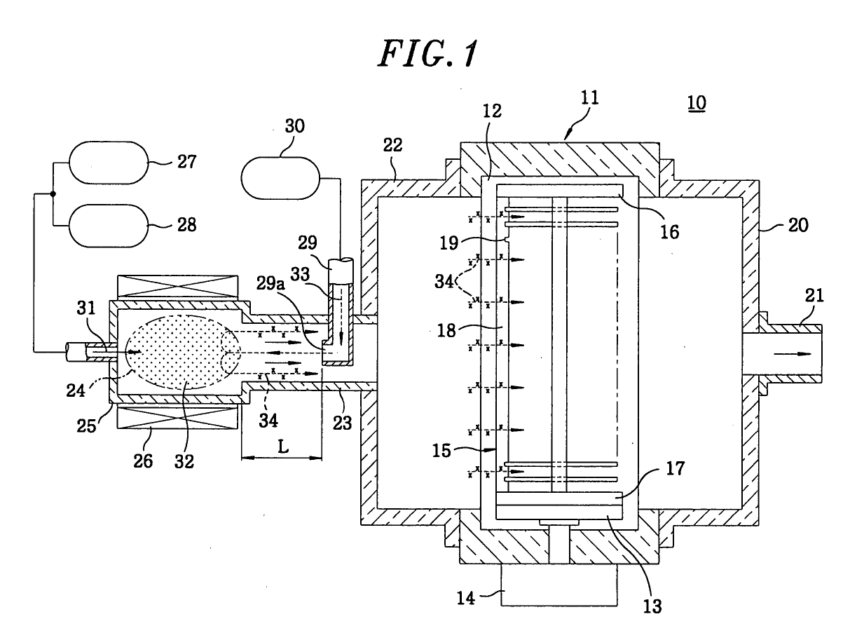

Referring to FIG. 1, there is illustrated a substrate processing apparatus in accordance with a first preferred embodiment of the present invention, which is a natural oxide films removing apparatus for removing a natural oxide film formed on a surface of a semiconductor wafer by using a remote plasma cleaning technique. As shown in FIG. 1, the natural oxide film removing apparatus 10 is configured to perform a batch process in which a plurality of the semiconductor wafers are simultaneously subject to a natural oxide film removing process.

As shown in FIG. 1, the natural oxide film removing apparatus 10 performing a batch process (hereinafter, referred to as a batch type natural oxide film removing apparatus) includes a process tube 11 forming therein a processing chamber 12 in which the natural oxide film removing process is carried out. The process tube 11 is of a single-bodied right circular cylinder made of quartz with both ends thereof closed. The process tube 11 is vertically installed such that the axial line thereof is perpendicular to the ground. The bottom end of the process tube 11 has a turntable 13 rotatably installed thereon for holding a boat 15. The turntable 13 is concentric with the bottom end and rotated by a rotary actuator 14 installed outside the process tube 11 at a lower surface of the bottom end.

As shown in FIG. 1, the boat 15 is disposed on the turntable 13 in order to accommodate therein a plurality of the wafers 1, wherein the turntable 13 rotates in unison with the boat 15. The boat 15 has an upper and a lower plate 16, 17 and support rods 18 (three support rods in this embodiment) vertically arranged therebetween. The support rods 18 have a plurality of vertically arranged wafer mount groove portions 19, such that a number of wafers can be held horizontally with an identical gap therebetween by the groove portions 19. The lower plate 17 of the boat 15 is removably fixed on an upper surface of the turntable 13. The wafers 1 are transferred into the process tube 11 through a wafer transfer opening (not shown) formed at a portion of the side wall of the processing chamber 12 by a wafer transfer device (not shown) in such a manner that the wafers 1 are horizontally and concentrically inserted into the wafer mount groove portions 19.

As shown in FIG. 1, an exhaust port 20 is connected to the side wall of the process tube 11 in such a manner that the exhaust port 20 communicates with the processing chamber 12, wherein height of the exhaust port 20 is approximately identical to that of the process tube 11. Connected to the exhaust port 20 is an exhaust line 21 for evacuating the process tube 11.

A gas supply port 22 is connected to a portion of the side wall of the process tube 11 opposite to the exhaust port 20 in such a manner that the gas supply port 22 communicates with the processing chamber 12, wherein the height of the gas supply port 22 is approximately same as that of the process tube 11. One end of a gas supply line 23 is connected to a middle portion of the gas supply port 22 in such a manner that the gas supply line 23 can horizontally supply gases into the processing chamber 12. The other end of the gas supply line 23 is connected to a plasma chamber 25 in which plasma 24 is formed. A plasma generator 26 is installed outside the plasma chamber 25 to generate the plasma 24 therein. The plasma generator 26 can be any of known types including inductively coupling types, such as an inductively coupled plasma (ICP) generation apparatus, capacitively coupled plasma (CCP) generation apparatus, an electron cyclotron resonance (ECR) type plasma generation apparatus, and a micro-surface wave plasma generation apparatus. A hydrogen gas (hereinafter referred to as H₂ gas) supply source 27 and a nitrogen gas (hereinafter N₂ gas) supply source 28 are connected to the plasma chamber 25 to supply H₂ and N₂ gases thereto. NH₃ gas may also be used alone or together with H₂ and/or N₂ gas.

In the gas supply line 23 connecting the plasma chamber 25 with the gas supply port 22, one end portion of an etching gas input line 29 is inserted and the other end thereof is connected to an NF₃ gas supply source 30 for supplying NF₃ gas to be activated. The inserted end portion of the etching gas input line 29 (hereinafter referred to as the NF₃ gas input line) is L-shaped such that an NF₃ gas injection hole 29a at the end of the NF₃ gas input line 29 faces the plasma chamber 25 along an axial line of the gas supply line 23 in order to inject NF₃ gas toward the plasma chamber 25.

Outside the process tube 11, a heater unit (not shown) including, e.g., a lamp heater for heating the processing chamber 12 is installed in such a manner that it does not interfere with the wafer transfer opening, the exhaust port 20 and the gas supply port 22.

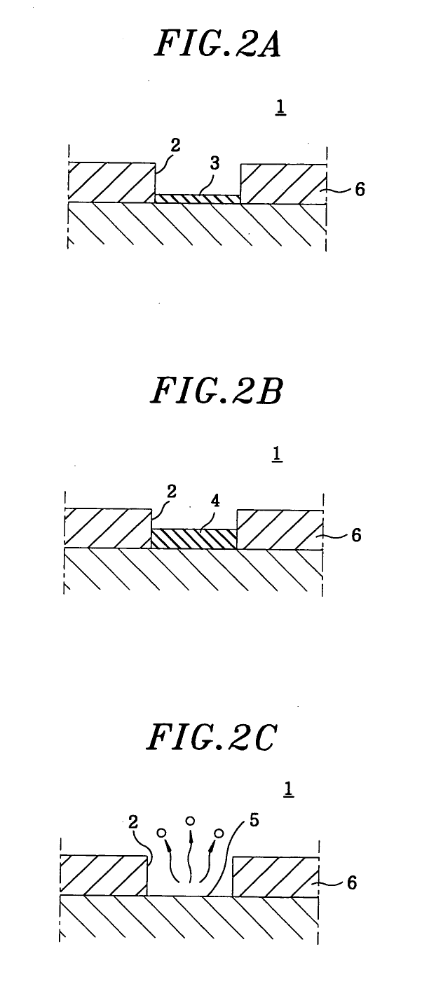

The operation of the batch type natural oxide film removing apparatus having the structure described above will now be illustrated. Referring to FIGS. 2A to 2C, it is assumed that a layer, e.g., an insulation layer 6 of a wafer 1 is provided with a contact hole 2 and there exists a natural oxide film 3 on a bottom surface of the contact hole 2.

As shown in FIG. 1, a plurality of such wafers 1 having natural oxide films 3 thereon are loaded in the boat 15 by the wafer transfer device to remove the natural oxide films. The wafer transfer opening is then airtightly closed by a gate valve (not shown). Thereafter the processing chamber 12 is evacuated through the exhaust line 21 and the turntable 13 holding the boat 15 is rotated by the rotary actuator 14.

A plasma 24 is created in the plasma chamber 25 by the plasma generator 26 with H₂ gas and N₂ gas (hereafter, a mixed gas 31) being supplied to the plasma chamber 25 from the H₂ gas and N₂ gas supply sources 27 and 28. Active gas species 32 are generated from the mixed gas 31 supplied to the plasma chamber 25 by the plasma discharge.

In addition, the NF₃ gas blown from a NF₃ gas injection hole 29a of the NF₃ gas input line 29 is supplied toward the plasma chamber 25 through the gas supply line 23. Then, the NF₃ gas is mixed with and activated by the active gas species 32. A natural oxide film removing gas 34 including the activated NF₃ gas, the mixed gas 31 and active gas species 32 flows into the processing chamber 12 through the gas supply port 22.

The natural oxide film removing gas 34 introduced into the processing chamber 12 is uniformly diffused across the processing chamber 12 to react with the natural oxide films 3 on the wafers 1 to thereby form reacted films 4 containing Si, N, H, F (hereinafter, a surface treated layer) as shown in FIG. 2B. Since the boat 15 holding the wafers 1 is rotated by the turntable 13 during the processing steps described above, the natural oxide film removing gas 34 can uniformly contact with front surfaces of the wafers 1.

After a predetermined period of time required for forming the surface treated films 4 has lapsed, the supply of H₂, N₂ and NF₃ gases from their corresponding gas sources 27, 28 and 30 is stopped and the plasma generator 26 also stops its operation. Further, the remaining gas in the processing chamber 12 is exhausted through the exhaust line 21.

After a predetermined period of time required for exhausting the processing chamber 12 has lapsed, the processing chamber 12 is heated by the heater unit to a predetermined temperature, e.g., 100° C., enabling the surface treated film 4 to be sublimated as shown in FIG. 2C. Consequently, the natural oxide films 3 formed on the wafers 1 are removed and Si surfaces 5 are exposed. A mechanism applied to the natural oxide film removing process is as follows: First, the natural oxide film removing gas including H₂, N₂ and NF₃ gases and active gas species thereof reacts with the natural oxide film (SiO₂) and then forms the surface treated film 4, i.e., a polymer containing Si, N, H and F. Next, the polymer is sublimated at a temperature of 100° C. or higher.

After a predetermined period of time required for sublimating the surface treated films has lapsed, the heater unit stops heating and the remaining gas in the processing chamber 12 is exhausted through the exhaust line 21.

After a predetermined period of time required for exhausting the remaining gas has lapsed, the wafers 1 are unloaded from the boat 15 and transferred to a wafer carrier (not shown) by the wafer transfer device through the wafer transfer opening opened by the gate valve.

The process steps described above are repeated to batch-process a number of wafers in the batch type oxide film removing apparatus 10.

The inventors of the present invention have found that plasma damage may occur on the wafer or a desired etching selectivity may not be obtained if the NF₃ gas 33, which greatly contributes to the natural oxide removing process, is directly supplied to the processing chamber 12 without going through the gas supply line 23 and mixed with and activated by the active gas species 32 of the mixed gas 31 in the processing chamber 12.

Since, however, the NF₃ gas 33 is injected toward the plasma chamber 25 and indirectly activated by the active gas species 32 after being introduced into the gas supply line 23 and the plasma chamber 25 in accordance with the preferred embodiment of the present invention, the plasma damage can be prevented and the required etching selectivity can be obtained. In other words, since the NF₃ gas 33 is supplied to the plasma chamber 25 and the supply line 23 and indirectly activated thereat by the active gas species 32, the natural oxide removing gas 34 can be introduced into the processing chamber 12 at a controlled decomposition rate of the NF₃ gas 33, so that the plasma damage on the wafer can be prevented and the desired etching selectivity can be achieved.

As shown in FIG. 1, the degree of decomposition reaction of the NF₃ gas 33 can be controlled in a wide range by varying the distance L between the NF₃ gas injection hole 29a of the NF₃ gas input line 29 and the plasma chamber 25. For example, by decreasing the distance L, the amount of NF₃ gas entering the plasma chamber 25 is increased so that the degree of decomposition or activation of the NF₃ gas is increased. Conversely, by increasing the distance L, the amount of NF₃ gas entering the plasma chamber 25 is decreased so that the degree of decomposition or activation of the NF₃ gas is decreased. It is preferable that the distance L is determined by an empirical method, e.g., experimentation or computer simulation by considering several conditions, e.g., a relation between an estimated volume of the natural oxide films to be removed and an area of the SiO₂ film not to be removed, a supply amount of the mixed gas 31 or NF₃ gas 33, and the like.

In accordance with the first preferred embodiment of the present invention, following effects can be obtained.

1) Since etching selectivity between the natural oxide film and silicon can be 8 by controlling the degree of decomposition rate of the NF₃ gas, which greatly contributes to the natural oxide film removal, the natural oxide film can be removed completely. For example, the natural oxide film can be removed with an etching rate equal to or greater than 3 Å/min.

2) By controlling the degree of the decomposition rate of the NF₃ gas, plasma damages on, e.g., the wafer, the process tube and the boat can be prevented from occurring.

3) Since the degree of the composition rate of the NF₃ gas can be controlled in a wide range by varying the distance L between the NF₃ gas injection hole of the NF₃ gas input line and the plasma chamber, the natural oxide film can be removed completely in any processing condition.

4) By supplying the natural oxide film removing gas parallel to main surfaces of the wafers loaded in the boat, the natural oxide film removing gas can be uniformly distributed across the main surfaces of the wafers, so the natural oxide film can be removed uniformly.

5) By rotating the boat holding the wafers thereon by using the turntable, the natural oxide film removing gas can contact with the front surfaces of the wafers uniformly, so that the natural oxide film can be removed uniformly.

6) For example, by disposing CVD film after removing the natural oxide film formed after pre-cleaning process, adverse effects of the natural oxide film on the CVD film can be completely prevented, so that the performance and reliability of a CVD apparatus can be improved and, further, the quality, reliability and yield of the semiconductor devices manufactured by the CVD apparatus can also be improved.

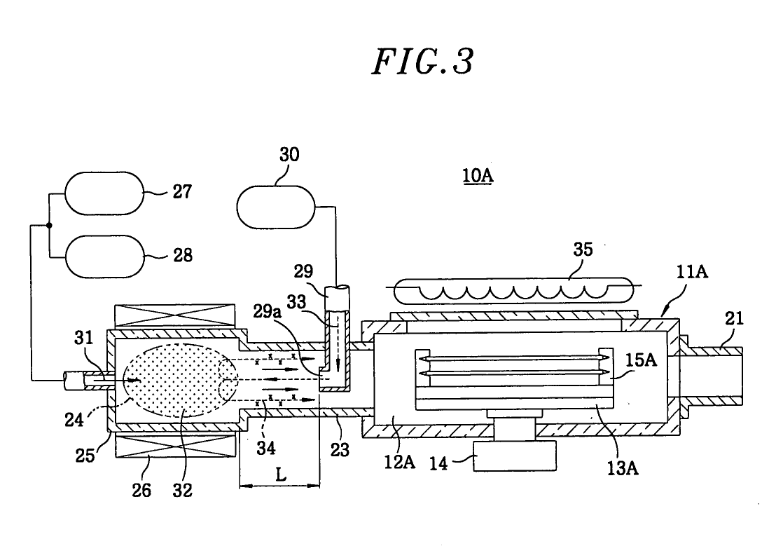

Referring to FIG. 3, there is shown a cross sectional view of a single wafer type natural oxide film removing apparatus in accordance with a second preferred embodiment of the present invention.

This embodiment is different from the former embodiment in that this embodiment processes wafers without a boat. In other words, the natural oxide film removing apparatus 10A in accordance with the second preferred embodiment includes a process tube 11A configured of a short right circular cylinder shape to form a processing chamber 12A of a low height. A wafer support 15A, instead of a boat, holding two wafers 1 is installed on a turntable 13A. Reference numeral 35 represents a heater unit formed of a lamp.

This preferred embodiment has the same effect as in the first preferred embodiment. In other words, by blowing the NF₃ gas 33 to the plasma chamber 25 through the gas supply line 23, the NF₃ gas can be activated in the gas supply line 23 and the plasma chamber 25 by the active gas species 32 of the mixed gas 31, so that the plasma damage can be prevented from occurring on the wafer 1 and the desired etching selectivity can be obtained.

Further, it should be apparent to those skilled in the art that the present invention is not limited to the preferred embodiments described above but can be variously modified without departing from the scope of the present invention.

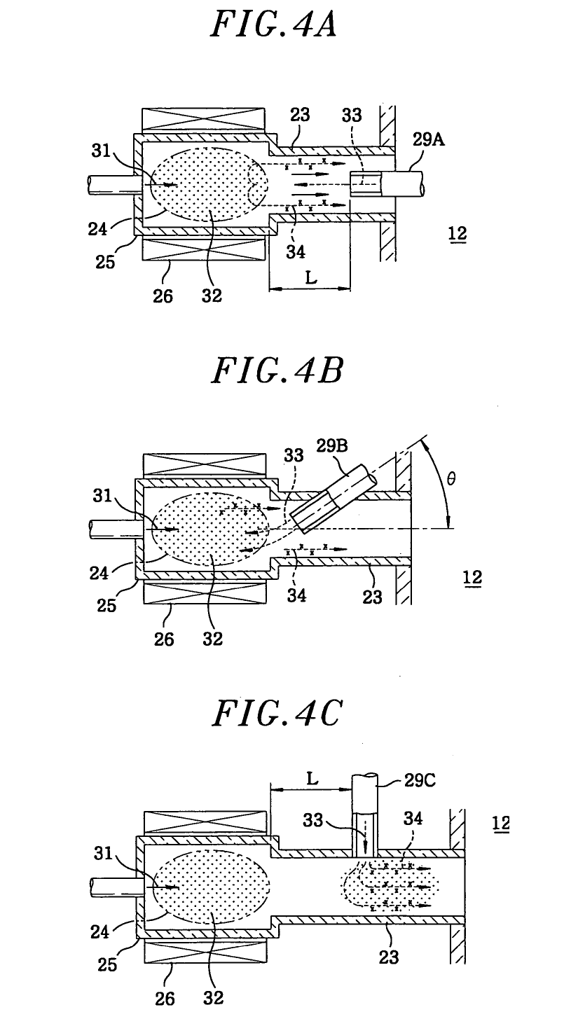

For example, the NF₃ gas input line can also be inserted in the gas supply line 23 as shown in FIGS. 4A to 4C.

Referring to FIG. 4A, there is shown an NF₃ gas input line 29A, which is inserted along the axial line of the gas supply line 23 at the end thereof abutting the processing chamber 12.

An experimental result obtained by using the NF₃ gas line structure shown in FIG. 4A will now be described in terms of the distance L and the etching rate. The experiment was performed under conditions, where the microwave power of the plasma generator 26 was 1800 W; the flow rate of the H₂ gas, 400 cc/min; the flow rate of the N₂ gas, 300 cc/min; flow rate of the NF₃, 1000 cc/min; the pressure in the processing chamber 12, 120 Pa; and the temperature of the wafer equal to or less than 40° C. When the distances L between the injection hole of NF₃ gas input line 29A and the plasma chamber 25 were 205 mm, 227 mm and 268 mm, corresponding etching rates were respectively 3.3 Å/min, 2.5 Å/min and 1.7 Å/min. Through this experiment, it has been found that sufficient etching rate can be obtained and that etching rate can be controlled by varying the distance L.

Referring to FIG. 4B, there is shown an NF₃ gas input line 29B, which is inserted in the gas supply line 23 at a sloping angle Θ. In this preferred embodiment, by varying the sloping angle Θ, the degree of activation or decomposition rate of the NF₃ gas can be adequately controlled in a wide range.

Referring to FIG. 4C, there is shown an NF₃ gas input line 29C, which is connected to the gas supply line 23 with an axial line thereof being perpendicular to that of the gas supply line 23. In this embodiment, the NF₃ gas input line 29C is not protruded into the gas supply line 23.

An experimental result obtained by using the structure shown in FIG. 4C under the same processing condition as in FIG. 4A showed that the etching rate was 0.3 Å/min when the distance L was 210 mm. However, when the injection hole of the NF₃ gas input line 29C was directed toward the processing chamber 12, etching seldom occurred. This results from the short activation time, i.e., NF₃ gas is readily evacuated and thus cannot stay with the activated gas species 32 of the H₂ gas and the N₂ gas for a period long enough to exchange sufficient energy.

It should be noted that the substrates to be processed can be photomasks, printed circuit substrates, liquid crystal panels, compact disks, magnetic disks or the wafers.

ClF₃, CF₄, C₂F₆ or other halogen gas can be used as an etching gas in lieu of the NF₃ gas.

In accordance with the preferred embodiments described above, the natural oxide film can be completely removed while preventing plasma damages as described above.

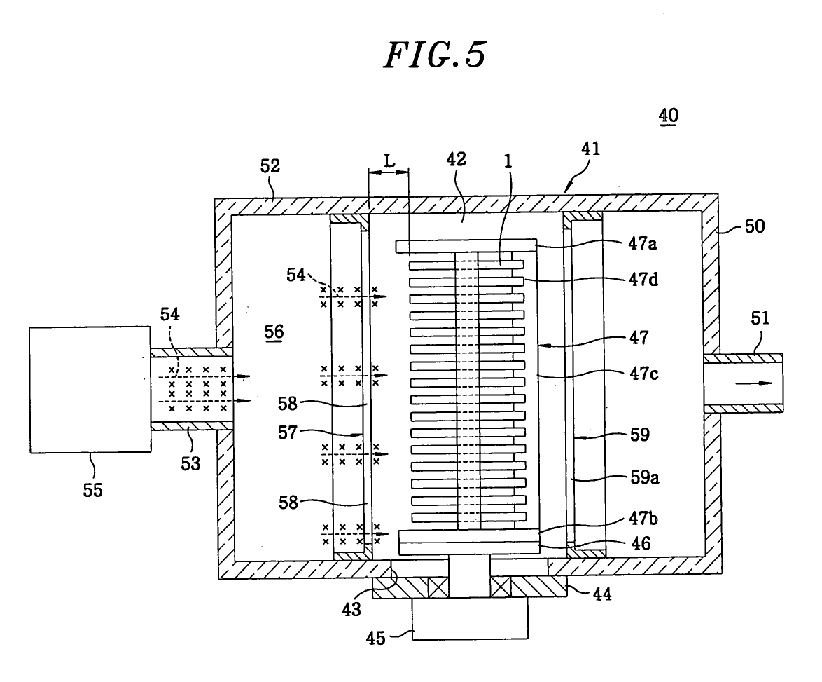

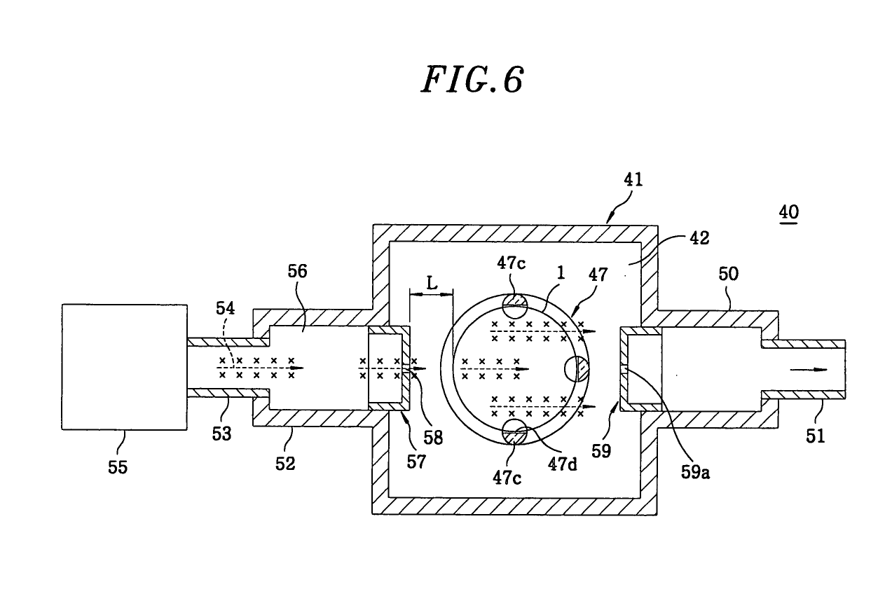

A third preferred embodiment of the present invention will now be described in detail with reference to FIGS. 5 and 6.

Referring to FIGS. 5 and 6, there are respectively illustrated a side and a top cross sectional views of the third preferred embodiment.

Natural oxide film removing apparatus in accordance with the third preferred embodiment removes natural oxide films formed on wafers by using a remote plasma cleaning method. The apparatus is configured as shown in FIGS. 5 and 6 and performs a batch process in which a plurality of wafers are simultaneously subject to a natural oxide film removing process.

As shown in FIGS. 5 and 6, the batch type natural oxide film removing apparatus 40 includes a process tube 41 for forming therein a processing chamber 42 in which natural oxide film removing process is performed. The process tube 41 is of a hexahedral box shape hermetically sealed to maintain vacuum inside and is installed vertically in such a manner that its central line is perpendicular to the ground. The process tube 41 includes a bottom wall having a boat loading/unloading opening 43. The boat loading/unloading opening 43 is opened and closed by a sealing cap 44, which can be vertically moved away from and toward the process tube 41 and lowered by a boat elevator (not shown). Under the sealing cap 44, a rotary actuator 45 is installed and its rotor is inserted into the processing chamber 42 through the sealing cap 44. A turntable 46 is horizontally disposed on an upper end of the rotor to thereby rotate in unison therewith.

As shown in FIG. 5, a boat 47 for holding a plurality of wafers 1 is installed on the turntable 46 so that the boat 47 and the turntable 46 can rotate in unison. The boat 47 is made of a ceramic such as quartz, alumina or aluminum nitride (AlN) to prevent, e.g., metal contamination of the wafers 1. The boat 47 includes an upper plate 47a, a lower plate 47b and several support rods 47c (three, in this embodiment) vertically disposed therebetween. The support rods 47c have a plurality of vertically arranged wafer mount groove portions 47d, such that a number of wafers 1 can be held horizontally with an identical gap therebetween by the groove portions 47d. The lower plate 47b of the boat 47 is removably fixed on an upper surface of the turntable 46.

As shown in FIGS. 5 and 6, an exhaust port 50 is connected to a portion of the side wall of the process tube 41 in such a manner that the exhaust port 20 communicates with the processing chamber 42, wherein height of the exhaust port 50 is approximately identical to that of the process tube 41.

A gas supply port 52 is connected to a portion of the side wall of the process tube 41 opposite to the exhaust port 50 in such a manner that the gas supply port 52 communicates with the processing chamber 42, wherein the height of the supply port 52 is approximately same as that of the process tube 41. One end of a gas supply line 53 is connected to a middle portion of the gas supply port 52 in such a manner that the gas supply line 53 can horizontally supply gases into the processing chamber 42. The other end of the gas supply line 53 is connected to a remote plasma unit 55, which activates NF₃ gas by using a high frequency electric power wave and so on.

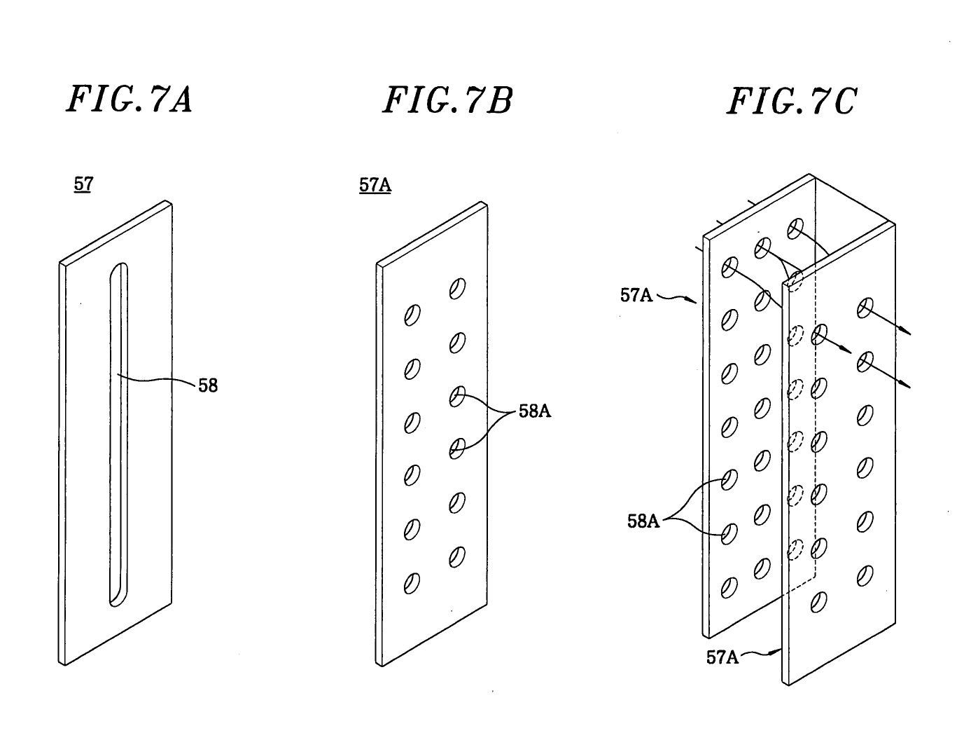

Provided at the end of the gas supply port 52 facing toward the process tube 41 is a distribution plate 57 for distributing a natural oxide film removing gas 54 in parallel to the wafers 1. At an upstream of the distribution plate 57, a buffer portion 56 for distributing the gas flow of the natural oxide film removing gas 54 is provided by the distribution plate 57. As shown in FIG. 7A, the distribution plate 57 has a vertical slit forming a gas injection opening 58, so that the natural oxide film removing gas can be distributed vertically therethrough and be horizontally introduced into the processing chamber 42. The distribution plate 57 is installed in such a manner that the distance L between the distribution plate 57 and proximal periphery of the wafer 1 is equal to or less than 50 mm. The distribution plate 57 not only serves to form the buffer portion 56 but also controls ion or radical energy.

Further, provided at the end portion of the exhaust port 50 facing toward the processing chamber 42 is a conductance plate 59 to uniformly evacuate the processing chamber 42 across the height thereof. The conductance plate 59 is provided with a gas exhaust opening 59a of a vertically elongated slit. The distance between the conductance plate 59 and the proximal periphery of the wafer 1 loaded in the boat 47 is set to be equal to or less than 50 mm.

The operation of the batch type natural oxide film removing apparatus 40 will now be described.

A plurality of wafers 1 required to be subject to the natural oxide film removing process are loaded in the boat 47 outside the processing chamber 42 by a wafer transfer device (not shown) and the boat 47 holding the wafers 1 is transferred to the processing chamber 42 through the boat loading/unloading opening 43. As shown in FIGS. 5 and 6, the processing chamber 42 is airtightly closed by the sealing cap 44 and exhausted through an exhaust line 51. The turntable 46 holding the boat 47 is turned by the rotary actuator 45.

Then, the natural oxide film removing gas 54 including the activated NF₃ gas is introduced into the gas supply port 52 from the remote plasma unit 55. The natural oxide film removing gas 54 introduced into the gas supply port 52 is uniformly distributed across the whole volume of the buffer portion 56 and flows into the processing chamber 42 uniformly across the height thereof through the gas injection opening 58 formed of the vertical slit. The flow of the natural oxide film removing gas 54 is distributed and its ion and radical energy are controlled to be reduced by the distribution plate 57. In addition, the conductance plate 59 uniformly distributes along the height thereof the exhausting force of the exhaust line 51, so that the natural oxide films removing gas 54 can be distributed more uniformly in the processing chamber 42.

The natural oxide film removing gas 54 introduced into the processing chamber 42 contacts the wafers 1 loaded in the boat 47 to react with and remove the natural oxide film with the preferable etching selectivity. At this moment, since the natural oxide film removing gas 54 is uniformly distributed in the processing chamber 42 by the distribution plate 57, the wafers 1 loaded in the boat 47 can contact equally with the natural oxide film removing gas 54 in regardless of their position, i.e., height, in the boat 47. Further, since the wafers 1 loaded in the boat 47 are rotated by the turntable 46, the natural oxide film removing gas 54 is also uniformly distributed across the entire surface of each wafer. Accordingly, even though the wafers 1 are disposed in the boat one above another, the natural oxide films of the wafers 1 can be entirely and uniformly removed.

Further, since the ion and radical energy of the natural oxide film removing gas 54 activated by the remote plasma unit 55 are controlled to be decreased by the distribution plate 57, the plasma damage can be prevented from occurring and the desired etching selectivity can be obtained.

If the inner side wall of the processing chamber is of a circular shape, the natural oxide film removing gas 54 flows along the inner side wall. Therefore, it is preferable that the inner side wall is configured to be concentric with the wafers and the gap between the inner side wall and the periphery of the wafers is small. However, the reduced gap between the inner side wall and the wafers requires high installation accuracy of the boat.

In this embodiment, a distance between periphery of the wafer 1 and the distribution plate 57 and that between periphery of the wafer 1 and the conductance plate 59 are set to be equal to or less than 50 mm. Therefore, even though the inner side wall of the processing chamber 42 is not configured to be of a circular shape and a distance between the inner side wall and the periphery of the wafers is not small, the natural oxide film removing gas 54 can efficiently flow and also can be supplied to the center portions of the wafer 1. Accordingly, the decrease of the etching rate of the natural oxide film can be prevented and at the same time etching uniformity can be improved. Further, since the gab between the inner side wall and wafer need not be small, the high installation accuracy of the boat is not required.

After a predetermined period of time for removing the natural oxide films has lapsed, the supply of the natural oxide film removing gas 54 from the remote plasma unit 55 and the rotation of the turntable 46 are stopped. Further, the remaining gas in the processing chamber 42 is exhausted through the exhaust line 51.

After a predetermined period of time for exhausting the remaining gas has passed, the boat 47 holding the processed wafers 1 is unloaded from the processing chamber 42 by the descent of the sealing cap 44. The processed wafers 1 are unloaded from the boat 47 by the wafer transfer device.

The processing steps described above are repeated to batch-process the remaining wafers to be processed by the batch type natural oxide film removing apparatus.

In accordance with the above embodiment, following effects can be obtained.

1) Since the natural oxide film removing gas is uniformly distributed across the processing chamber 42 by the distribution plate, the wafers loaded in the boat can contact uniformly with the natural oxide film removing gas in regardless of their position, i.e., height, in the boat. Accordingly, even though the wafers are disposed in the boat one above another, the natural oxide films of the wafers can be removed entirely and uniformly. Namely, natural oxide films formed on a plurality of wafers in the boat can be removed at a time, so throughput can be higher when compared to that of the single wafer type natural oxide film removing apparatus.

2) The ion and radical energy of the natural oxide film removing gas activated in the remote plasma unit are controlled to be reduced by the distribution plate. Accordingly, even if the natural oxide film removing gas contacts with the wafers, the plasma damage can be prevented and the etching selectivity can be obtained so that the natural oxide film can be removed adequately.

3) Since the ion and radical energy of the natural oxide film removing gas can be controlled by setting the distance between the diffusion plate and the periphery of the wafer within 50 mm, the etching selectivity between the natural oxide film and the silicon can be over 8. Therefore, the natural oxide film can be removed completely. For example, the natural oxide film can be removed at 3 Å/min.

4) The distance between periphery of the wafer and the distribution plate 57 and between periphery of the wafer and the conductance plate are set to be equal to or less than 50 mm, even though the inner side wall of the processing chamber is not configured to be of a circular shape and the gap between the inner wall and the periphery of the wafer is not small, the natural oxide film removing gas can efficiently flow. As a result, the decrease of the removal rate of the natural oxide film removing gas can be prevented and removal uniformity thereof can be increased.

5) By supplying the natural oxide film removing gas parallel to main surfaces of the wafers loaded on the boat, the natural oxide film removing gas can be uniformly distributed across the main surfaces of the wafers, so the natural oxide film can be removed uniformly.

6) By rotating the boat holding the wafers therein by using the turntable, the natural oxide film removing gas can contact with the front surfaces of the wafers uniformly, so that the natural oxide films can be removed uniformly.

7) For example, by disposing CVD film after removing the natural oxide film formed after pre-cleaning process, adverse effects of the natural oxide film on the CVD film can be completely prevented, so that the performance and reliability of a CVD apparatus can be improved and, further, the quality, reliability and yield of the semiconductor devices manufactured by the CVD apparatus can also be improved. By supplying the natural oxide film removing gas with the flow direction thereof parallel to the front surface of the wafer, the natural oxide film removing gas can contact uniformly with the front surfaces of the wafers, so the natural oxide films can be removed uniformly.

Further, it should be apparent to those skilled in the art that the present invention is not limited to the preferred embodiments described above but can be variously modified without departing from the scope of the present invention.

For instance, a distribution plate 57A shown in FIG. 7B having a plurality of gas injection openings 58A made of circular holes can be used in lieu of the distribution plate 57 shown in FIG. 7A, which has the vertical slit as the gas injection opening 58.

Further, the number of the distribution plate is not limited to one. For instance, two parallel distribution plates 57A can be used as shown in FIG. 7C. It is also possible to install two or more distribution plates, e.g., having different structures, including the distribution plate 57 with the gas injection opening 58 of the vertically extended slit and the distribution plate 57 A with the gas injection openings 58A of a plurality of holes. In addition, it is also possible to install two or more distribution plates, which are not disposed in parallel.

As described above, by varying the shapes and sizes of the gas injection openings of the distribution plates as well as the number of the distribution plates installed and the installation interval and angle thereof, distribution of the natural oxide film removing gas and ion and radical energies can be optimally controlled and thus the etching selectivity of the natural oxide film removing gas and the removing uniformity can be controlled adequately.

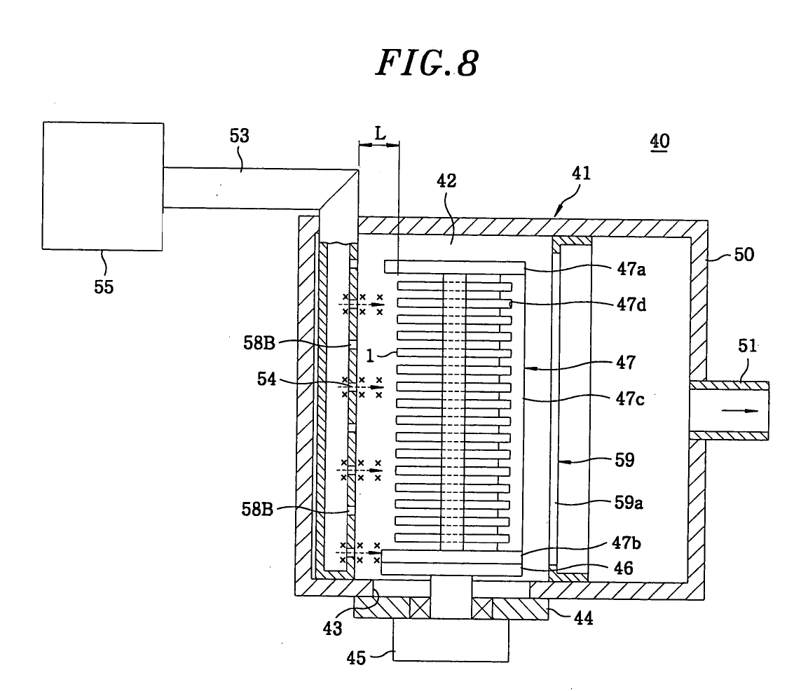

Furthermore, as shown in FIG. 8, the gas supply line 53 can be installed to be vertically extended into the processing chamber 42 wherein a plurality of gas injection openings 58B can be formed along the gas supply line 53 inserted in the processing chamber 42. Since the natural oxide film removing gas is evenly supplied between the wafers held in the boat 47 and also uniformly contacts with the whole surface of each wafer, the same effects as in the preferred embodiments described above can also be obtained in this case.

Since the HSG film is not formed well on the wafer having the natural oxide film thereon, it is necessary to remove the natural oxide film before forming the HSG layer. However, once the wafer treated by the natural oxide film removing process is exposed to the ambient air, the HSG film is not adequately formed even after subjecting the wafer to the HSG film forming process in a substrate processing apparatus, e.g., CVD apparatus. Although the reason why the HSG film is not formed is not clearly revealed, it is suspected that the by-product is attached on the wafer when the natural oxide film is removed and thereafter reacts with certain elements in the ambient air to prevent the HSG film from forming. Accordingly, it is preferable that the by-product is sublimated before the by-product reacts with the elements in the ambient air.

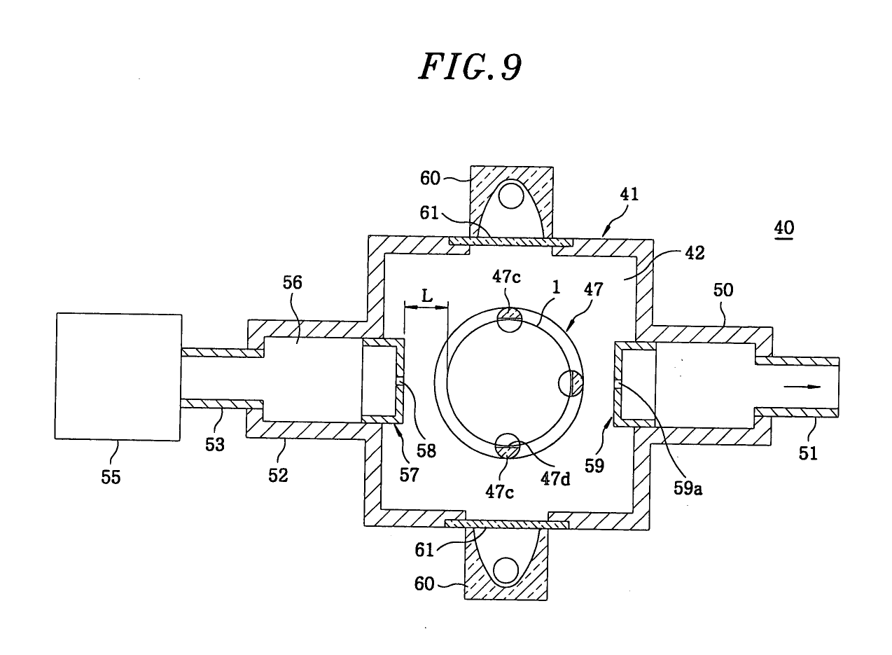

Referring to FIG. 9, there is shown a batch type natural oxide film removing apparatus 40A in accordance with another preferred embodiment of the present invention, which is capable of sublimating the by-product in the processing chamber 42 before the by-product reacts with the elements in the ambient air. The apparatus 40A of the instant preferred embodiment is different from the apparatus 40 shown in FIG. 6 in that lamp heaters 60 are configured to heat the processing chamber 42 through irradiation windows 61.

In this preferred embodiment, the processing chamber 42 is heated to 80° C. or higher by the irradiation of the lamp heaters 60 through the irradiation windows 61 made of quartz glass to sublimate the by-product attached on the wafers 1 after the removal of the natural oxide film by the natural oxide film removing gas 54. It was found that the HSG film was formed adequately during the subsequent HSG forming process after the aforementioned heat treatment. The natural oxide film removed surface of the wafer can be further stabilized by being subject to a hydrogenation process.

Further, it should be noted other types of heaters, e.g., resistive heater or the like, can also be used in lieu of the lamp heaters.

In the preferred embodiment described, the by-products has been described as being removed in the processing chamber being heated. Since, however, the HSG film forming process can be accomplished as long as the by-product is removed before being exposed to the ambient air, the natural oxide film removing process and the by-product removing process need not be necessarily carried in a single chamber. In other words, the heater unit may be installed at a different heat treatment chamber connected to the processing chamber having no heater unit. In that case, the natural oxide film is removed in the processing chamber first and then transferred in vacuum or in the inert gas atmosphere to the heat treatment chamber to remove the by-product therein.

It should be apparent to those skilled in the art that the distribution plates described above with respect to FIGS. 5 to 8 can be also used in the first and the second preferred embodiments described with respect to FIGS. 1 and 3.

It is also to be understood the present invention can be applied to heat treating photomasks, printed circuit board or liquid crystal panel, compact disk or magnetic disk as well.

While the invention has been shown and described with respect to the preferred embodiments, it will be understood by those skilled in the art that various changes and modifications may be made without departing from the spirit and scope of the invention as defined in the following claims.

1-6. (canceled)

7. A natural oxide films removing apparatus, comprising:
a processing chamber which is evacuated;
a plasma generating chamber in which a plasma is created;
a gas supply line connecting the processing chamber with the plasma generating chamber;
a first gas input line which is provided with a gas injection hole and supplies a first gas into the gas supply line through the gas injection hole; and
a second gas input line which is attached to the plasma generating chamber and supplies a second gas into the gas supply line,
wherein a natural oxide film removing gas including the first gas activated by the second gas activated by a plasma discharge is supplied to the processing chamber through the gas supply line to remove a natural oxide film on a wafer,
wherein the first gas input line is inserted in the gas supply line such that the gas injection hole at the end of the first gas input line faces towards the plasma generating chamber,
wherein the gas injection hole is disposed in a flow of the second gas in the gas supply line and an angle between a direction along which the first gas is injected into the flow of the second gas in the gas supply line through the gas injection hole and a direction of the flow of the second gas at the gas injection hole in the gas supply line is greater than 90° but equal to or smaller than 180°, and
wherein when the angle is 180°, the flow of the first gas is counter-current to the flow of the second gas.

8. The apparatus of claim 7, wherein the first gas is NF₃ gas and the second gas includes at least hydrogen gas and nitrogen gas or ammonia gas.

9. The apparatus of claim 7, further comprising a distribution device means for distributing the natural oxide film removing gas to flow parallel to the wafer.

10. The apparatus of claim 9, wherein the means for distributing the natural oxide film removing gas to flow parallel to the wafer includes one or more distribution plates, each having at least one gas injection opening.

11. A substrate processing apparatus, comprising:
a processing chamber which is evacuated;
a plasma generating chamber in which a plasma is created;
a gas supply line connecting the processing chamber with the plasma generating chamber;
a first gas input line which is provided with a gas injection hole and supplies a first gas into the gas supply line through the gas injection hole; and
a second gas input line which is attached to the plasma generating chamber and supplies a second gas into the gas supply line,
wherein a reaction gas including the first gas activated by the second gas activated by a plasma discharge is supplied to the processing chamber through the gas supply line to process a wafer,
wherein the first gas input line is inserted in the gas supply line such that the gas injection hole at the end of the first gas input line faces towards the plasma generating chamber,
wherein the gas injection hole is disposed in a flow of the second gas in the gas supply line and an angle between a direction along which the first gas is injected into the flow of the second gas in the gas supply line through the gas injection hole and a direction of the flow of the second gas at the gas injection hole in the gas supply line is greater than 90° but equal to or smaller than 180°, and
wherein when the angle is 180°, the flow of the first gas is counter-current to the flow of the second gas.

12. The apparatus of claim 7, wherein distance between the gas injection hole and the plasma chamber is not more than 268 mm.

13. The apparatus of claim 7, wherein a direction along which the first gas is injected into the flow of the second gas in the gas supply line through the gas injection hole is the reverse of a direction of the flow of the second gas at the gas injection hole in the gas supply line.
